(19) United States
(12) Patent Application Publication
(10) Pub. No.: US 2011/0026337 A1
(43) Pub. Date: Feb. 3, 2011

(54) DATA INPUT/OUTPUT CIRCUIT AND SEMICONDUCTOR MEMORY APPARATUS INCLUDING THE SAME

(75) Inventor: Seung Wook KWACK, Ichon-si (KR)

Correspondence Address: Echelon Law Group, PC, 1919 Gallows Road., Suite 330, Vienna, VA, 22182, US

(73) Assignee: HYNIX SEMICONDUCTOR INC., Ichon-si (KR)

(21) Appl. No.: 12/645,384

(22) Filed: Dec. 22, 2009

(30) Foreign Application Priority Data
Jul. 30, 2009 (KR) 10-2009-0070090

(51) Int. Cl. G11C 7/00; G11C 8/00

(52) U.S. Cl. 365/193; 365/230.03

(57) ABSTRACT

A circuit includes a data input/output unit configured to connect to a first memory bank and a second memory bank. The data input/output unit includes a data switching unit configured to be selectively coupled with the first or second memory bank in response to a bank selection signal, and an input/output driver configured to amplify an output of the data switching unit and transfer the amplified output to a global data line during the read operation, and configured to amplify data from the global data line and transfer the amplified data to the data switching unit during the write operation.

### CROSS-REFERENCE TO RELATED APPLICATIONS

The present application claims priority under 35 U.S.C 119(a) to Korean Application No. 10-2009-0070090, filed on Jul. 30, 2009, with the Korean Intellectual Property Office, which is incorporated herein by reference in its entirety as set forth in full.

### BACKGROUND

1. Technical Field

The embodiments described herein relate to semiconductor memory apparatuses, and more particularly, to data input/output circuits of semiconductor memory apparatus.

2. Related Art

With an increase in operation rates of semiconductor memory apparatuses, the addition of stacked bank structures into these apparatuses have been proposed to improve the efficiency of data access. In the stacked bank structure, a memory cell area is divided into a plurality of memory blocks. Each memory block is composed of a plurality of stacked memory banks.

FIG. 1 is a schematic diagram of a configuration of a conventional semiconductor apparatus. As shown in FIG. 1, the semiconductor memory apparatus is comprised of four memory banks (BANK 0-BANK 3) 11-14 and four input/output drivers 21-24. The first and second memory banks 11 and 12 and the third and fourth memory banks 13 and 14 form stacked bank structures, respectively. The first input/output driver 21 writes or reads data into/from memory cells of the first memory bank 11 through local input/output lines (e.g., LIO_up0/LIOB_up0). Similarly, the second, third and fourth input/output drivers 22, 23, and 24 write/read data into/from memory cells in the second, third and fourth memory banks 12, 13, and 14 through local input/output lines (e.g., LIO_dn1/LIOB_dn1, LIO_up2/LIOB_up2, and LIO_dn3/LIOB_dn3), respectively.

The local input/output line LIO_up0/LIOB_up0, coupled with the first memory bank 11, sends data to a first global input/output line GIO1 through the first input/output driver 21. The first global data input/output line GIO1 is coupled with a first data input/output pad DQ1. During a read operation, data from a memory cell of the first memory bank is transferred to the local input/output line LIO_up0/LIOB_up0 by an amplification operation of a bit-line sense amplifier (not shown). The data is then amplified by the first input/output driver 21, transferred to the first global input/output line GIO1, and transferred to an external system through the first data input/output pad DQ1. The opposite takes place during a write operation. During a write operation, data from the first data input/output pad DQ1 is transferred to the first global input/output line GIO1. The data transferred into the first input/output driver 21 is amplified, transferred to the local input/output line LIO_up0/LIOB_up0, and then stored in a memory cell of the first memory bank 11.

As seen in FIG. 1, the input/output drivers are provided for reading/writing data from/into memory cells of their respective memory banks in the semiconductor memory apparatus with such a stacked bank structure. They also independently conduct data input/output operations each to their respective memory banks. However, arranging the input/output drivers concurrently to their respective memory banks would cause the semiconductor memory apparatus to be increased in layout size. This layout makes it harder to scale down the semiconductor memory apparatus.

### SUMMARY

One embodiment of the present invention includes a circuit which comprises a data input/output unit configured to connect to a first memory bank and a second memory bank. The data input/output unit includes: a data switching unit configured to be selectively coupled with the first or second memory bank in response to a bank selection signal; and an input/output driver configured to amplify an output of the data switching unit and transfer the amplified output to a global data line during the read operation, and configured to amplify data from the global data line and transfer the amplified data to the data switching unit during the write operation.

Another embodiment of the present invention includes a semiconductor memory apparatus capable of conducting a read operation and a write operation, which comprises: a first local input/output line electrically connected to a first memory bank; a second local input/output line electrically connected to a second memory bank; and a common input/output driving unit configured to amplify read data from one of the first and second local input/output lines in response to a bank selection signal and to transfer the amplified read data to a global data line during the read operation, and configured to amplify write data from the global data line and to selectively transfer the amplified write data to one of the first and second local input/output lines in response to the bank selection signal during the write operation.

Another embodiment of the present invention includes a method of controlling input/output data for a read/write operation in a semiconductor memory apparatus, which comprises: enabling data transfer from an input/output driver to a plurality of memory banks; selecting one of the plurality of memory banks to transfer data; and performing the read or write operation with the selected memory bank.

### BRIEF DESCRIPTION OF THE DRAWINGS

Features, aspects, and embodiments are described in conjunction with the attached drawings, in which;

FIG. 1 is a schematic diagram of a configuration of a conventional semiconductor apparatus;

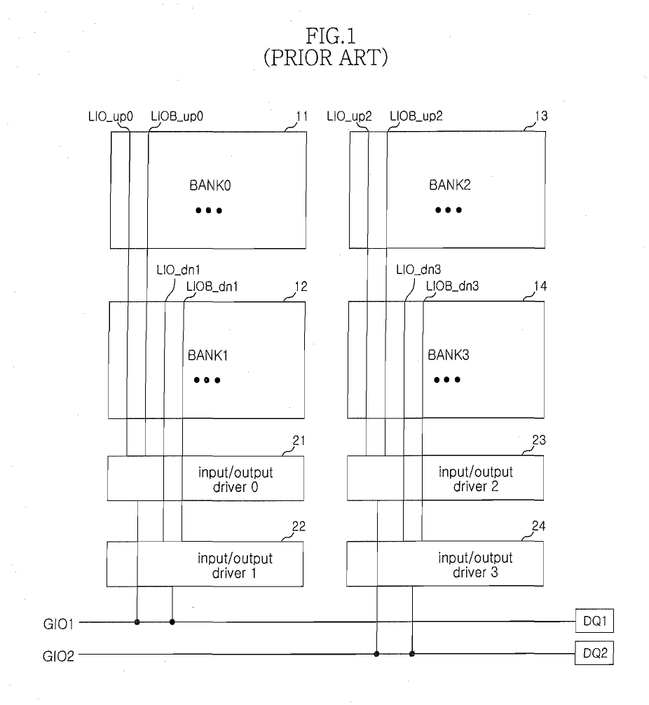

FIG. 2 is a diagram of a configuration of a semiconductor apparatus according to exemplary embodiments of the present invention;

FIG. 3 is a diagram of an embodiment of the common input/output driving unit shown in FIG. 2;

FIG. 4 is a diagram of an embodiment of the control unit shown in FIG. 2;

FIG. 5 is a diagram of an embodiment of the bank selection signal generator shown in FIG. 2; and

FIG. 6 is a timing diagram of an operation of the semiconductor memory apparatus, according to exemplary embodiments of the present invention.

### DESCRIPTION OF EMBODIMENTS

Hereinafter, semiconductor memory apparatuses and a test method thereof, according to the present invention, will be described below with reference to the accompanying drawings through exemplary embodiments.

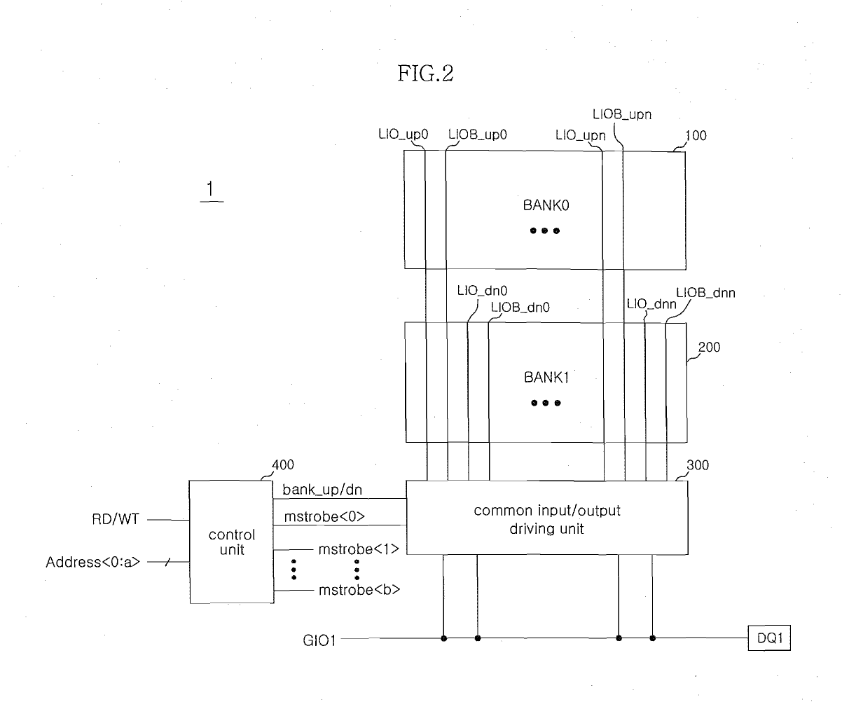

FIG. 2 is a schematic diagram of a semiconductor memory apparatus 1 according to an exemplary embodiment of the present invention. Referring to FIG. 2, the semiconductor memory apparatus 1 can include a first memory bank 100, a second memory bank 200, a common input/output driving unit 300 and a control unit 400.

In this embodiment, the first and second memory banks 100 and 200 form a stacked bank structure. The memory banks 100 and 200 forming the stacked bank structure share the same input/output lines and the same input/output pad. Thus, data is output/input to/from an external system using the shared input/output lines and input/output pad. As shown in FIG. 2, data transferred through a shared data input/output pad DQ1 and a global input/output line GIO1 is stored into the first and second memory banks 100 and 200. Likewise, data stored in the first and second memory banks 100 and 200 is transferred to an external system via the global input/output line GIO1 and the data input/output pad DQ1.

The first and second memory banks 100 and 200 include a plurality of memory cells and are electrically connected to a plurality of local input/output lines, i.e., LIO_up0/LIOB_up0-LIO_upn/LIOB_upn and LIO_dn0/LIOB_dn0-LIO_dnn/LIOB_dnn, respectively. In a read operation, data is transferred from a memory cell in the first memory bank 100 to the global input/output line GIO1 via the local input/output lines LIO_up0/LIOB_up0-LIO_upn/LIOB_upn. In a write operation, data is also transferred from the global input/output line GIO1 to memory cells in the first memory bank 100 also via the local input/output lines LIO_up0/LIOB_up0-LIO_upn/LIOB_upn. Similarly, in a read operation, data is transferred from a memory cell in the second memory bank 200 to the global input/output line GIO1 via the local input/output lines LIO_dn0/LIOB_dn0-LIO_dnn/LIOB_dnn. In a write operation, data is transferred from the global input/output line GIO1 to a memory cell in the second memory bank 200 via the local input/output lines LIO_dn0/LIOB_dn0-LIO_dnn/LIOB_dnn.

During the read operation, the common input/output driving unit 300 amplifies data from the first and second local input/output lines LIO_up0/LIOB_up0-LIO_upn/LIOB_upn and LIO_dn0/LIOB_dn0-LIO_dnn/LIOB_dnn and transfers the amplified data to the global input/output line GIO1. During the write operation, the common input/output driving unit 300 amplifies data from the global input/output line GIO1 and transfers the amplified data to the first and second local input/output lines LIO_up0/LIOB_up0-LIO_upn/LIOB_upn and LIO_dn0/LIOB_dn0-LIO_dnn/LIOB_dnn. The common input/output driving unit 300 is selectively coupled with one of the first and second memory banks 100 and 200 in response to a bank selection signal ‘bank_up/dn’. In other words, the common input/output driving unit 300 is electrically connected to the alternative of the first local input/output lines LIO_up0/LIOB_up0-LIO_upn/LIOB_upn coupled to the first memory bank 100, and the second local input/output lines LIO_dn0/LIOB_dn0-LIO_dnn/LIOB_dnn coupled to the second memory bank 200, in response to the bank selection signal ‘bank_up/dn’.

When the read or write operation is executed, the bank selection signal ‘bank_up/dn’ selects either the first or second memory bank, 100 or 200. For instance, if the bank selection signal ‘bank_up/dn’ is active, the read/write operation is conducted to the first memory bank 100. On the other hand, if the bank selection signal ‘bank_up/down’ is inactive, the read/write operation is conducted to the second memory bank 200.

When the first memory bank begins the read operation in response to ‘bank_up/dn’ signal being active, the common input/output driving unit 300 amplifies and transfers the memory bank's data via the first local input/output lines LIO_up0/LIOB_up0-LIO_upn/LIOB_upn to the global input/output line GIO1. On the other hand, if the ‘bank_up/dn’ signal is inactive, the second memory bank 200's data is transferred via the second local input/output lines LIO_dn0/LIOB_dn0-LIO_dnn/LIOB_dnn to the global input/output line GIO1.

In the write operation, the common input/output driving unit 300 amplifies data from the global input/output line GIO1. If the bank selection signal ‘bank_up/dn’ is active, the common input/output driving unit 300 transfers the amplified data to the first memory bank 100 via the first local input/output lines LIO_up0/LIOB_up0-LIO_upn/LIOB_upn. If the bank selection signal ‘bank_up/dn’ is inactive, the common input/output driving unit 300 transfers the amplified data to the second memory bank 100 via the second local input/output lines LIO_up0/LIOB_up0 LIO_upn/LIOB_upn.

The control unit 400 may generate a main strobe signal ‘mstrobe<0>’ and the bank selection signal ‘bank_up/dn’ in response to a read/write command ‘RD/WT’ and a bank address ‘Address<0:a>’. The read/write command ‘RD/WT’ is a command signal applied externally through a pad, enabling the semiconductor memory apparatus to execute the read/write operation. The bank address ‘Address<0:a>’, applied to the semiconductor memory apparatus through a pad or a plurality of pads, designates the particular memory bank to output or store data. The main strobe signal, ‘mstrobe<0>’, enables the common input/output driving unit 300 to amplify data in the read/write operation. The control unit 400 will be explained in more detail later.

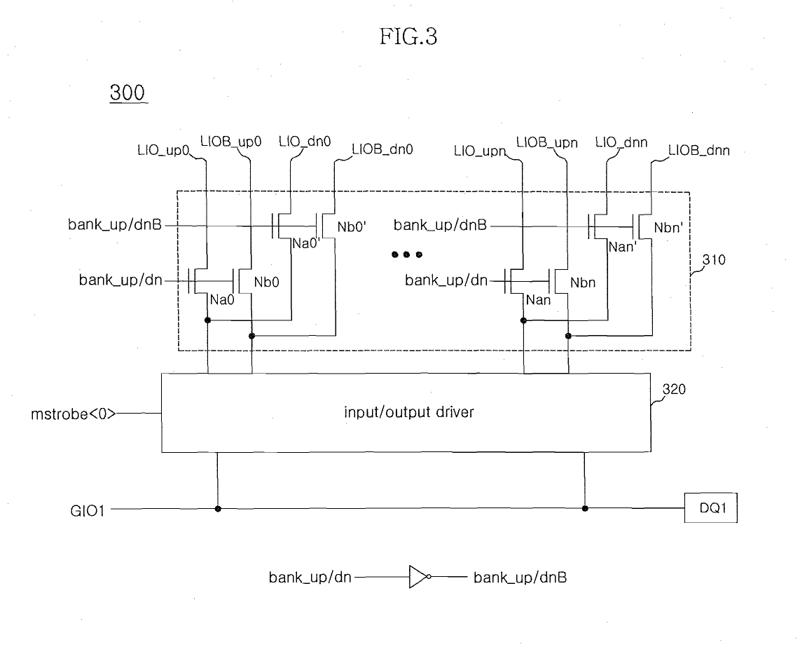

FIG. 3 is a schematic diagram of the common input/output driving unit shown in FIG. 2. Referring to FIG. 3, the common input/output driving unit 300 may include a data switching unit 310 and an input/output driver 320.

The data switching unit 310 transfers data from the alternative of the first and second local input/output lines, i.e., LIO_up0/LIOB_up0-LIO_upn/LIOB_upn and LIO_dn0/LIOB_dn0-LIO_dnn/LIOB_dnn. In the read operation, the data switching unit 310 transfers data from the first local input/output lines LIO_up0/LIOB_up0-LIO_upn/LIOB_upn if the bank selection signal ‘bank_up/dn’ is active, or from LIO_dn0/LIOB_dn0-LIO_dnn/LIOB_dnn if it is inactive. In the write operation, the data switching unit 310 transfers data from the input/output driver 320 to the first local input/output lines LIO_up0/LIOB_up0-LIO_upn/LIOB_upn if the bank selection signal ‘bank_up/dn’ is active, or from LIO_dn0/LIOB_dn0-LIO_dnn/LIOB_dnn if ‘bank_up/dn’ is inactive.

As illustrated in FIG. 3, the data switching unit 310 may be composed of transistors Na0-Nan and Nb0-Nbn and transistors Na0′-Nan′ and Nb0′-Nbn′. One terminal of each of the transistors Na0-Nan and Nb0-Nbn is coupled to each of the first local input/output lines LIO_up0/LIOB_up0-LIO_upn/LIOB_upn, respectively. One terminal of the transistors Na0′-Nan′ and Nb0′-Nbn′ is coupled to each of the second local input/output lines LIO_dn0/LIOB_dn0-LIO_dnn/LIOB_dnn, respectively. The transistors Na0-Nan and Nb0-Nbn receive the bank selection signal ‘bank_up/dn’ through their gates and are turned on if the bank selection signal ‘bank_up/dn’ is active. The transistors Na0′-Nan′ and Nb0′-Nbn′ receive an inverted signal of the bank selection signal ‘bank_up/dn’ (‘bank_up/dnB’) through their gates, and are turned on if the bank selection signal ‘bank_up/dn’ is inactive. The other terminals of the transistors Na0-Nan and Nb0-Nbn act as input terminals of the input/output driver 320 and are each coupled with the corresponding channel ends of the transistors Na0′-Nan′ and Nb0′-Nbn′. Thus, the data switching unit 310 is able to select the alternative of the first and second local input/output lines LIO_up0/LIOB_up0-LIO_upn/LIOB_upn and LIO_dn0/LIOB_dn0-LIO_dnn/LIOB_dnn in response to the bank selection signal bank_up/dn. In FIG. 3, the data switching unit 310 is made up of NMOS transistors, but it is possible to use other switching elements capable of properly selecting the first and second local input/output lines LIO_up0/LIOB_up0-LIO_upn/LIOB_upn and LIO_dn0/LIOB_dn0-LIO_dnn/LIOB_dnn.

During the read operation, the input/output driver 320 amplifies and provides data output from the data switching unit 310 to the global input/output line GIO1. During the write operation, the input/output driver 320 amplifies data from the global input/output line GIO1 and transfers the amplified data to the data switching unit 310. Although not shown in FIG. 3, the input/output driver 320 has the same number of unit input/output drivers as the first local input/output lines LIO_up0/LIOB_up0-LIO_upn/LIOB_upn coupled to the first memory bank 100, or the second local input/output lines LIO_dn0/LIOB_dn0-LIO_dnn/LIOB_dnn coupled to the second memory bank 200. In other words, the input/output driver 320 has the same number of unit input/output drivers as the local input/output lines do.

In the read operation, each unit input/output driver amplifies and transfers data from the data switching unit 310 to the global input/output line GIO1. In the write operation, each input/output driver unit amplifies data from the global input/output line GIO1 and transfers the amplified data to the data switching unit 310.

In a conventional case, each memory bank has to be equipped with its own input/output driver for transferring data from the first and second memory banks of the stacked bank structure or storing data in the first and second memory banks. In this embodiment, the data switching unit 310 shares the input/output driver 320 with the first and second memory banks 100 and 200 of the stacked bank structure, reducing the number of conventional input/output drivers by up to fifty percent.

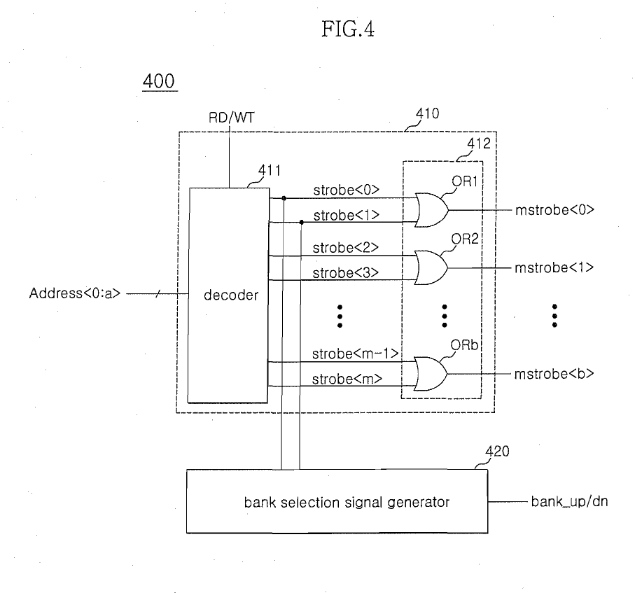

FIG. 4 is a block diagram of the control unit shown in FIG. 2. In FIG. 4, the control unit 400 is comprised of a strobe signal generator 410 and a bank selection signal generator 420. The strobe signal generator 410 generates a plurality of strobe signals ‘strobe<0:m>’ in response to the read/write command ‘RD/WT’ and the bank address ‘Address<0:a>’. The plurality of strobe signals ‘strobe<0:m>’ are used to generate the main strobe signal ‘mstrobe<0:b>’.

In FIG. 4, the strobe signal generator 410 includes a decoder 411 and a strobe consolidator 412. The decoder 411 operates to decode the bank address ‘Address<0:a>’ and generates the strobe signals ‘strobe<0:m>’ by combining the decoded results with the read/write command ‘RD/WT’. The bank address ‘Address<0:a>’ is a signal for selecting a memory bank which the read/write command enables. For instance, a semiconductor memory apparatus that has 8 memory banks accepts 3 bits of the bank address. Since 8 decoding signals can be generated by decoding the 3 bits of the bank address, the 8 memory banks are selected independently.

Hereinafter, the case of providing the bank address with 3 bits for 8 memory banks will be exemplifed. The decoder 411 generates 8 strobe signals ‘strobe<0:7>’ from the 3 bits of the bank address ‘Address<0:2>’. For example, the decoder 411 activates the first strobe signal ‘strobe<0>’ to transfer data into/from the first memory bank 100 if the read/write command ‘RD/WT’ is applied and the first bank address ‘Address<0>’ is active. Similarly, the decoder 411 activates the second strobe signal ‘strobe<1>’ to transfer data into/from the second memory bank 200 if the read/write command ‘RD/WT’ is applied and the second bank address ‘Address<1>’ is active.

The strobe consolidator 412 generates the main strobe signals ‘mstrobe<0:b>’ in response to the plurality of strobe signals ‘strobe<0:m>’ from the decoder 411. The strobe consolidator 412 may be formed of a plurality of OR gates, OR1, OR2, . . . , and Orb, each receiving strobe signals relevant to the two stacked memory banks. When the first and second strobe signals are combined, the OR gate OR1 generates the main strobe signal ‘mstrobe<0>’. The main strobe signal enables the input/output driver 320 to conduct the read/write operations for the first and second memory banks 100 and 200 of the stacked structure. The strobe signals are also directly related to the read/write operation of the first and second memory banks 100 and 200. The second strobe signal, ‘strobe<1>’, instructs the second memory bank 200 to be read or written; similarly, the first strobe signal ‘strobe<0>’ instructs the first memory bank 100 to be read or written.

The main strobe signals ‘strobe<1:b>’ generated from the OR gates OR2-Orb may be used as signals for controlling another input/output driver associated with other stacked memory banks (not shown in FIG. 3).

From the plurality of strobe signals ‘strobe<0:m>, the bank selection signal generator 420 transfers the bank selection signal ‘bank_up/dn’, relevant to the first and second memory banks 100 and 200. For instance, assuming that the first strobe signal ‘strobe<0>’ is related to the first memory bank 100 and the second strobe signal ‘strobe<1>’ is related to the second memory bank 200, the bank selection signal generator 420 outputs the bank selection signal ‘bank_up/dn’ from the first and second strobe signals ‘strobe<0>’ and ‘strobe<1>’.

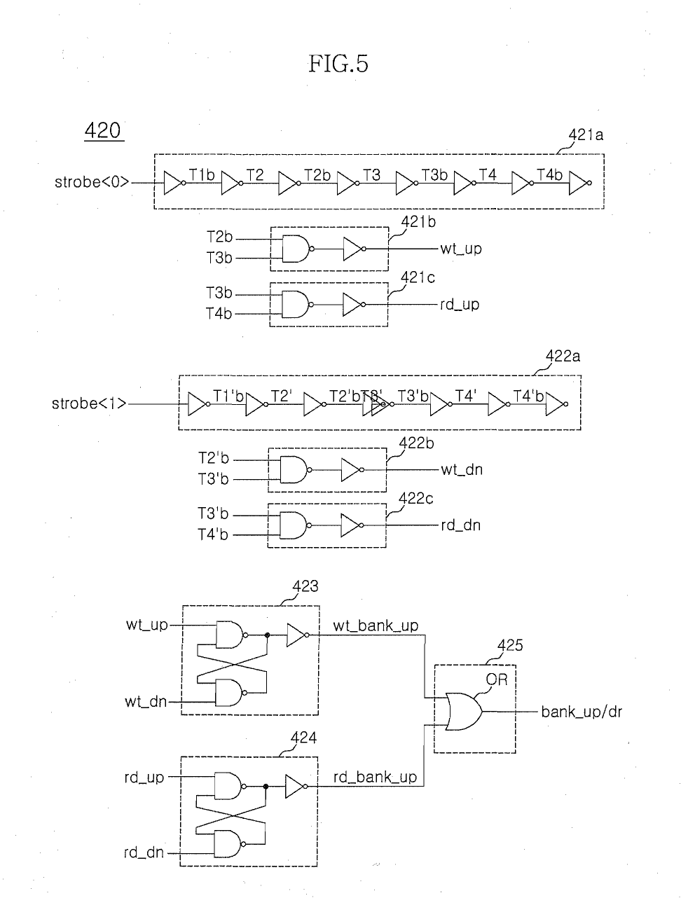

FIG. 5 is a block diagram of the bank selection signal generator 420 shown in FIG. 2. Referring to FIG. 5, the bank selection signal generator 420 is comprised of first and second delay circuits 421a and 422a, first through fourth pulse generators 421b, 421c, 422b and 422c, first and second SR latches 423 and 424, and a signal combiner 425.

The first delay circuit 421a operatively delays the first strobe signal ‘strobe<0>’ by a unit time generated by 8 serially coupled inverters. The first pulse generator 421b outputs an up-write signal ‘wt_up’ from the delayed signal combination ‘T2b’ and ‘T3b’. The second pulse generator 421c outputs an up-read signal ‘rd_up’ from the delayed signal combination ‘T3b’ and ‘T4b’. Similarly, the second delay circuit 422a utilizes 8 serially coupled inverters to delay the second strobe signal ‘strobe<1>’. The third pulse generator 422b outputs a down-write signal ‘wt_dn’ from the delayed signal combination ‘T2′b’ and ‘T3′b’. The fourth pulse generator 422c outputs a down-read signal ‘rd_dn’ from the delayed signal combination ‘T3′b’ and ‘T4′b’.

The first SR latch 423 receives the up-write signal ‘wt_up’ and the down-write signal ‘wt_dn’. In response to the activation of the up-write signal ‘wt_up’, the first SR latch 423 activates and substantially maintains an up-bank write signal ‘wt_bank_up’ until the down-write signal ‘wt_dn’ is activated. The second SR latch 424 receives the up-read signal ‘rd_up’ and the down-read signal ‘rd_dn’. In response to activation of the up-read signal ‘rd_up,’ the second SR latch 424 activates and substantially maintains an up-bank read signal ‘rd_bank_up’ until the down-read signal ‘rd_dn’ is activated.

In response to the up-bank write signal ‘wt_bank_up’ and the up-bank read signal ‘rd_bank_up’, the signal combiner 425 generates the bank selection signal ‘bank_up/dn’ If the up-bank write signal ‘wt_bank_up’ or the up-bank read signal ‘rd_bank_up’ is activated, the signal combiner 425 activates the bank selection signal ‘bank_up/dn’ to select the first memory bank 100. The signal combiner 425 inactivates the bank selection signal ‘bank_up/dn’ if the up-bank write signal ‘wt_bank_up’ and the up-bank read signal ‘rd_bank_up’ is inactivated, which in turn selects the second memory bank 200. The signal combiner 425 may be composed of OR gate ‘OR’.

Although not shown in the drawings, column selection signals operably connect the local bit line pairs to bit line pairs coupled with memory cells of the memory banks. Like the strobe signals, these column selection signals are generated from the read/write command ‘RD/WT’ and the bank address ‘Address<0:a>’. A delay circuit can activate the column selection signal on time despite variations of pressure, voltage and temperature (PVT variations). In this embodiment, the bank selection signal ‘bank_up/dn’ couples one of the first and second local input/output lines, LIO_up0/LIOB_up0-LIO_upn/LIOB_upn and LIO_dn0/LIOB_dn0-LIO_dnn/LIOB_dnn. In the read/write operation with the input/output driver 320, the bank selection signal ‘bank_up/dn’ may be generated in a similar manner with the column selection signal. Therefore, the bank selection signal generator 420 is formed to generate the bank selection signal ‘bank_up/dn’ on time regardless of PVT variations.

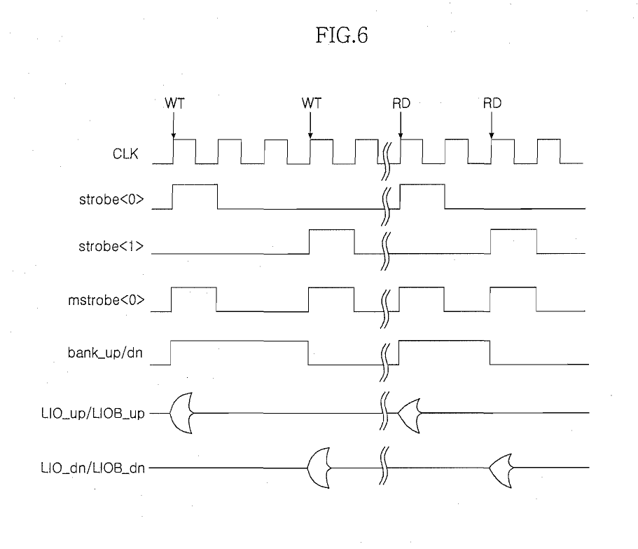

FIG. 6 shows a timing sequence of the read/write operation in the semiconductor memory apparatus according to an exemplary embodiment of the present invention. Referring to FIGS. 2 through 6, the read/write operation of the semiconductor memory apparatus 1 will be hereinafter described. For the read/write operation, a series of write commands ‘WT’ and read commands ‘RD’ are applied to the semiconductor memory apparatus from an external system in synchronization with a clock signal “CLK” 1. Here the first write command ‘WT’ is related to the first memory bank 100 and the second write command ‘WT’ is related to the second memory bank 200. Similarly, the first read command ‘RD’ is related to the first memory bank 100 and the second read command ‘RD’ is related to the second memory bank 200. The decoder 411 of the strobe signal generator 410 outputs the first and second strobe signals ‘strobe<0>’ and ‘strobe<1>’, as shown in FIG. 6. The strobe consolidator 412 generates the main strobe signal ‘mstrobe<0>’ by combining the first and second strobe signals ‘strobe<0:1>’. Meanwhile, the bank selection signal generator 420 outputs the bank selection signal ‘bank_up/dn’ from the first and second strobe signals ‘strobe<0:1>’.

During the cycle of the first write operation, the input/output driver 320 amplifies data from the global data line GIO1 in response to the main strobe signal ‘mstrobe<0>’. The data switching unit 310 couples the input/output driver 320 with the first local input/output lines LIO_up0/LIOB_up0-LIO_upn/LIOB_upn connected to the first memory bank 100 in response to the active bank selection signal ‘bank_up/dn’. Data amplified by the input/output driver 320 is then transferred to the first local input/output lines LIO_up0/LIOB_up0-LIO_upn/LIOB_upn. The amplified data transferred to any of the first input/output lines LIO_up0/LIOB_up0-LIO_upn/LIOB_upn is stored in the memory cell of the first memory bank 100.

During the cycle of the second write operation, the input/output driver 320 amplifies data from the global data line GIO1 in response to the second pulse of the main strobe signal ‘mstrobe<0>’. The data switching unit 310 couples the input/output driver 320 with the second local input/output lines LIO_dn0/LIOB_dn0-LIO_dnn/LIOB_dnn connected to the second memory bank 200 in response to the inactivity of the bank selection signal ‘bank_up/dn’. Data amplified by the input/output driver 320 is then transferred to the second local input/output lines LIO_dn0/LIOB_dn0-LIO_dnn/LIOB_dnn. The amplified data transferred to the second input/output lines LIO_dn0/LIOB_dn0-LIO_dnn/LIOB_dnn is stored in the memory cell of the second memory bank 200.

During the cycle of the first read operation, the data switching unit 310 couples the first local input/output lines LIO_up0/LIOB_up0-LIO_upn/LIOB_upn with the input/output driver 320 in response to the active bank selection signal ‘bank_up/dn’. The input/output driver 320 then amplifies data from the any of first local input/output lines LIO_up0/LIOB_up0-LIO_upn/LIOB_upn and transfers the amplified data to the global input/output line GIO1. Therefore, data stored in the first memory bank 100 is transferred through any of the first input/output lines LIO_up0/LIOB_up0-LIO_upn/LIOB_upn, through the common data input/output pad DQ1, to the external system.

During the cycle of the second read operation, the data switching unit 310 couples the second local input/output lines LIO_dn0/LIOB_dn0-LIO_dnn/LIOB_dnn with the input/output driver 320 in response to the inactive bank selection signal ‘bank_up/dn’. The input/output driver 320 then amplifies data from any of the second local input/output lines LIO_dn0/LIOB_dn0-LIO_dnn/LIOB_dnn and transfers the amplified data to the global input/output line GIO1. Therefore, data stored in the second memory bank 200 is transferred through any of the second input/output lines LIO_dn0/LIOB_dn0-LIO_dnn/LIOB_dnn, through the common data input/output pad DQ1, to the external system.

Since the input/output driver 320 shared by the stacked memory banks amplifies data every time a read/write operation occurs, and the data switching unit 310 responds to the bank selection signal ‘bank_up/dn’ to designate which one of the plural memory banks is to be used with the current read/write operation, there is no need to have the same number of input/output drivers and memory banks. Consequently, the layout margin of the semiconductor memory apparatus is greatly improved. While the embodiments describe two stacked memory banks (e.g., 100 and 200) sharing the input/output driver, it is also permissible to arrange three or more stacked memory banks sharing the input/output driver. When three stacked memory banks share the input/output driver, the number of the input/output drivers can be reduced than ⅓ over the semiconductor memory apparatus, so that the layout margin of the semiconductor memory apparatus will be further enlarged.

While certain embodiments have been described above, it is understood by those skilled in the art that the embodiments described are examples only. Accordingly, the device and method described herein should not be limited based on the described embodiments. Rather, the apparatus described herein should only be limited in light of the claims that follow when taken in conjunction with the above description and accompanying drawings.

What is claimed is:

1. A circuit, comprising:
a data input/output unit configured to connect to a first memory bank and a second memory bank, the data input/output unit including:
a data switching unit configured to be selectively coupled with the first or second memory bank in response to a bank selection signal; and
an input/output driver configured to amplify an output of the data switching unit and transfer the amplified output to a global data line during the read operation, and configured to amplify data from the global data line and transfer the amplified data to the data switching unit during the write operation.

2. The circuit according to claim 1, wherein, during the read operation, the data switching unit is configured to transfer first data from the first memory bank when the bank selection signal selects the first memory bank and to transfer second data from the second memory bank when the bank selection signal selects the second memory bank.

3. The circuit according to claim 1, wherein, during the write operation, the data switching unit is configured to transfer a first output of the input/output driver to the first memory bank when the bank selection signal selects the first memory bank and configured to transfer a second output of the input/output driver to the second memory bank when the bank selection signal selects the second memory bank.

4. The circuit according to claim 1, further comprising a control unit configured to generate a main strobe signal and the bank selection signal in response to an address and a read/write command.

5. The circuit according to claim 4, wherein the control unit comprises:
a strobe signal generator configured to generate a plurality of strobe signals based on the address and the read/write command, and to generate the main strobe signal by consolidating the strobe signals; and
a bank selection signal generator configured to generate the bank selection signal in response to the strobe signals related to the first and second memory banks.

6. The circuit according to claim 1, wherein the first and second memory banks are configured to form a stacked bank structure.

7. A semiconductor memory apparatus capable of conducting a read operation and a write operation, comprising:
a first local input/output line electrically connected to a first memory bank;
a second local input/output line electrically connected to a second memory bank; and
a common input/output driving unit configured to amplify read data from one of the first and second local input/output lines in response to a bank selection signal and to transfer the amplified read data to a global data line during the read operation, and configured to amplify write data from the global data line and to selectively transfer the amplified write data to one of the first and second local input/output lines in response to the bank selection signal during the write operation.

8. The semiconductor memory apparatus according to claim 7, wherein the common input/output driving unit comprises:
a data switching unit configured to select one of the first and second local input/output lines in response to the bank selection signal; and
an input/output driver configured to amplify an output of the data switching unit and to transfer the amplified output to the global data line during the read operation, and configured to amplify the write data from the global data line and to transfer the amplified write data to the data switching unit during the write operation.

9. The semiconductor memory apparatus according to claim 8, wherein, during the read operation, the data switching unit is configured to transfer the read data from the first local input/output line when the bank selection signal selects the first memory bank, and configured to transfer the read data from the second local input/output line when the bank selection signal selects the second memory bank.

10. The semiconductor memory apparatus according to claim 8, wherein, during the write operation, the data switching unit is configured to transfer the amplified write data of the input/output driver to the first local input/output line when the bank selection signal selects the first memory bank and configured to transfer the amplified write data of the input/output driver to the second local input/output line when the bank selection signal selects the second memory bank.

11. The semiconductor memory apparatus according to claim 7, further comprising a control unit configured to generate a main strobe signal and a bank selection signal in response to an address and a read/write command.

12. The semiconductor memory apparatus according to claim 11, wherein the control unit comprises:
a strobe signal generator configured to generate a plurality of strobe signals based on the address and the read/write command and configured to generate the main strobe signal based on the strobe signals; and
a bank selection signal generator configured to generate the bank selection signal in response to the strobe signals related to the first and second memory banks.

13. The semiconductor memory apparatus according to claim 7, wherein the first and second memory banks are configured to form a stacked bank structure.

14. A method of controlling input/output data for a read/write operation in a semiconductor memory apparatus, comprising:
enabling data transfer from an input/output driver to a plurality of memory banks;
selecting one of the plurality of memory banks to transfer data; and
performing the read or write operation with the selected memory bank.

15. The method according to claim 14, further comprising:
decoding an address signal and a read/write command to generate a plurality of strobe signals corresponding to one of the plurality of memory banks; and
consolidating the strobe signals into a main strobe signal to be applied to the input/output driver.

16. The method according to claim 15, wherein one of the memory banks is selected in response to a bank selection signal generated from the plurality of strobe signals.
